(19) United States
(12) Patent Application Publication
(10) Pub. No.: US 2024/0141495 A1
(43) Pub. Date: May 2, 2024

(54) CASSETTE STRUCTURES AND RELATED METHODS FOR BATCH PROCESSING IN EPITAXIAL DEPOSITION OPERATIONS

(71) Applicant: Applied Materials, Inc., Santa Clara, CA (US)

(72) Inventor: Aniketnitin PATIL, San Jose, CA (US)

(21) Appl. No.: 18/382,114

(22) Filed: Oct. 20, 2023

Related U.S. Application Data
(60) Provisional application No. 63/419,970, filed on Oct. 27, 2022.

(51) Int. Cl. C23C 16/458

(52) U.S. Cl. CPC C23C 16/4585; C23C 16/4581

(57) ABSTRACT

A cassette support system is disclosed and includes a pedestal assembly, with a shaft, a plurality of arms coupled to the shaft and extending radially from the shaft, wherein at least two radially adjacent arms included in the plurality of arms are separated by an angle of about 130 degrees or greater, a plurality of cassette supporting arms, with each cassette supporting arm extending from an end of an arm included in the plurality of arms, and one or more substrate support rings, wherein each substrate support ring includes a ridge defined along an inner circumference of the substrate support ring where the ridge configured to receive a substrate.

### CROSS-REFERENCE TO RELATED APPLICATIONS

This application claims benefit of U.S. provisional patent application Ser. No. 63/419,970, filed Oct. 27, 2022, which is herein incorporated by reference in its entirety.

### BACKGROUND

### Field

The present disclosure relates to cassette structures and related methods for batch processing in epitaxial deposition operations.

### Description of the Related Art

Semiconductor substrates are processed for a wide variety of applications, including the fabrication of integrated devices and microdevices. However, operations (such as epitaxial deposition operations) can be long, expensive, and inefficient, and can have limited capacity and throughput. Operations can also be limited with respect to film growth rates. Moreover, hardware can involve relatively large dimensions that occupy higher footprints in manufacturing facilities. Additionally, operations can involve hindrances with temperature control, gas control, and/or substrate center-to-edge control and adjustability. Such hindrances can be exacerbated in relatively complex processing operations, and/or in operations that call for one-sided deposition.

Therefore, a need exists for improved apparatuses and methods in semiconductor processing.

### SUMMARY

The present disclosure relates to cassette structures and related methods for batch processing in epitaxial deposition operations.

A cassette support system is disclosed and includes in one embodiment, a pedestal assembly, with a shaft, a plurality of arms coupled to the shaft and extending radially from the shaft, wherein at least two radially adjacent arms included in the plurality of arms are separated by an angle of about 130 degrees or greater, a plurality of cassette supporting arms, with each cassette supporting arm extending from an end of an arm included in the plurality of arms, and one or more substrate support rings, wherein each substrate support ring includes a ridge defined along an inner circumference of the substrate support ring where the ridge configured to receive a substrate.

In another embodiment a cassette support system is provided. The cassette support system includes a pedestal assembly with a shaft, a plurality of arms coupled to the shaft and extending radially from the shaft, wherein at least two radially adjacent arms included in the plurality of arms are separated by an angle of about 130 degrees or greater, a plurality of cassette supporting arms, each cassette supporting arm extending from a different arm included in the plurality of arms, and at least one substrate support ring, including a ridge defined along an inner circumference of each of the at least one substrate support ring.

In another embodiment a cassette support system is provided. The cassette support system includes a pedestal assembly with a shaft, three or more arms coupled to the shaft and extending radially from the shaft, wherein two radially adjacent arms included in the three or more arms are separated by an angle of about 130 degrees or greater, three or more cassette supporting arms, each cassette supporting arm extending from a different arm of the three or more arms; and three or more substrate support rings, including a ridge defined along an inner circumference of each of the substrate support rings as well as a first set of spacers disposed between a first substrate support ring and a second substrate support ring, wherein each spacer is disposed around a corresponding vertical cassette supporting arm and a second set of spacers disposed between the second substrate support ring and a third substrate support ring, wherein each spacer is disposed around a corresponding vertical cassette supporting arm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional side view of a processing apparatus with a plurality of substrates in a processing position in a cassette, according to one or more embodiments.

FIG. 2 is a schematic cross-sectional side view of the apparatus shown in FIG. 1 in an unloading position, according to one or more embodiments.

FIG. 3 is a schematic side cross-sectional view of the apparatus shown in FIG. 2 with a substrate lifted by lift pins for placement on two fingers of a robot arm and removal from the chamber, according to one or more embodiments.

FIG. 4 is a schematic side cross-sectional view of the apparatus shown in FIGS. 2 and 3, with the substrate deposited on the two fingers of the robot arm and the lift pins retracted, according to one or more embodiments.

FIG. 5 is a perspective view of an upper portion of a pedestal assembly used to support the cassette shown in FIGS. 1-4, according to one or more embodiments.

FIG. 6 is a top view of the upper portion of the pedestal assembly used to support the cassette shown in FIGS. 1-4, according to one or more embodiments.

FIG. 7 is a perspective view of a cassette, according to one or more embodiments.

FIG. 8 is a schematic side partial cross-sectional view of the cassette with a plurality of substrates housed therein, according to one or more embodiments.

FIG. 9 is a top view, partially in section, depicting an upper portion of the pedestal, lift pins, a substrate and a robot arm and fingers.

To facilitate understanding, identical reference numerals have been used, where possible, to designate identical elements that are common to the figures. It is contemplated that elements and features of one or more embodiments may be beneficially incorporated in other embodiments without further recitation.

### DETAILED DESCRIPTION

The present disclosure relates to cassette structures and related methods for batch processing in epitaxial deposition operations.

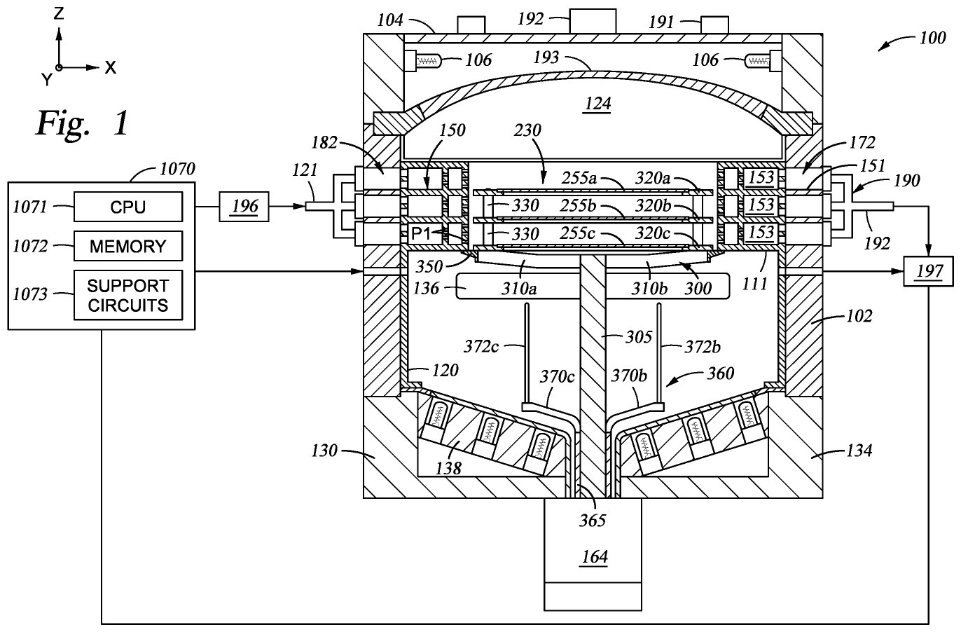

FIG. 1 is a schematic cross-sectional side view of a processing apparatus with a plurality of substrates in a processing position in a cassette, according to one implementation. The processing apparatus 100 includes a processing chamber having a chamber body 130 that defines a processing volume 124 as well as upper 106 and lower 138 heat sources.

The processing apparatus 100 includes a plurality of gas inject passages 182 formed in the chamber body 130 and in fluid communication with the processing volume 124, and one or more gas exhaust passages 172 (a plurality is shown in FIG. 1) formed in the chamber body 130 opposite the plurality of gas inject passages 182. The one or more gas exhaust passages 172 are in fluid communication with the processing volume 124. Each of the plurality of gas inject passages 182 and one or more gas exhaust passages 172 are formed through one or more sidewalls of the chamber body 130 and through one or more liners 120 that line the one or more sidewalls of the chamber body 130.

The processing apparatus 100 includes a flow guide structure 150 positioned in the processing volume 124. The flow guide structure 150 includes one or more first flow dividers 151 that divide the processing volume into a plurality of flow levels 153. During operations (such as during an epitaxial deposition operation), one or more process gases P1 are supplied to the processing volume 124 through the supply conduit system 121 and through the plurality of gas inject passages 182. The one or more process gases P1 are supplied from one or more gas sources 196 in fluid communication with the plurality of gas inject passages 182. Each of the gas inject passages 182 is configured to direct the one or more processing gases P1 in a generally radially inward direction towards the cassette 230. As such, in one or more embodiments, the gas inject passages 182 may be part of a cross-flow gas injector. The flow(s) of the one or more process gases P1 are divided into the plurality of flow levels 153. The division of process gas(es) into the plurality of flow levels 153 facilitates uniform processing (e.g., deposition) onto the substrates, center-to-edge uniformity, and process adjustability.

The processing apparatus 100 includes an exhaust conduit system 190. The one or more process gases P1 can be exhausted to an optional common exhaust box and then out through a conduit using one or more pump devices 197 (such as one or more vacuum pumps).

A cassette 230 is positioned in the processing volume 124 and at least partially supported by pedestal assembly 300. In various embodiments, the cassette 230 supports a plurality of substrates 255a, 255b, 255c for simultaneous processing (e.g., epitaxial deposition). In the embodiment shown in FIG. 1, the cassette 230 supports three substrates. However, the cassette 230 can support other numbers of substrates, including but not limited to two substrates 255, three substrates 255, six substrates 255, twelve substrates 255, etc.

The processing apparatus 100 includes a window 193, such as a dome, disposed above the cassette 230 and below the upper heat sources 106. The heat sources 106, 138 are positioned to provide uniform heating of the substrates 255. The one or more heat sources can be radiant heat sources, such as lamps. For example, halogen lamps and/or other heat sources may be used (in addition to or in place of the lamps) for the various heat sources described herein. In other examples, resistive heaters, light emitting diodes (LEDs), and/or lasers may be used for the various heat sources described herein.

The processing apparatus 100 includes a pedestal assembly 300 disposed in the processing volume 124. One or more liners 120 are disposed in the processing volume 124 and surround the pedestal assembly 300. The one or more liners 120 facilitate shielding the chamber body 130 from processing chemistry in the processing volume 124. The one or more liners 120 are disposed between the processing volume 124 and the chamber body 130. Additionally, a seal ring 350 disposed on the pedestal assembly 300 below the cassette 230 sealingly protects the chamber body 130 from process gases when the cassette is in a processing position in the chamber. In the embodiment shown, the ring 350 seals against a shield ring 111 adjacent gas inlet and exhaust structures during processing.

In some embodiments, the pedestal assembly 300 can be raised to a first position so that the cassette 230 is positioned within the processing volume 124. The pedestal assembly 300 can be lowered to a second position so that the cassette 230 of the chamber body 130 at which one or more substrates 255 can be loaded on the cassette 230 and/or unloaded from the cassette 230.

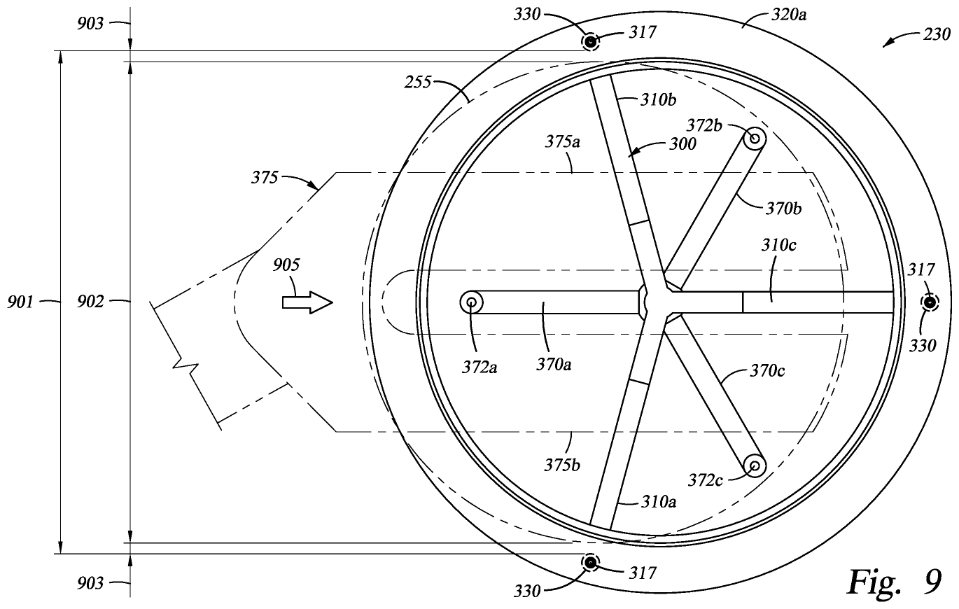

Separate from the pedestal assembly 300 is the lift pin assembly 360. In the embodiment shown, the lift pin assembly 360 is disposed outside of the pedestal assembly 300 with a coaxial shaft 365 axially movable independent of a pedestal shaft 305. Extending from the shaft 365 are three arms 370a, 370b, 370c (FIG. 9) each having a vertical lift pin 372a, 372b, 372c at a distal end thereof. As described below in conjunction with FIGS. 1-4 the lift pins 372 are utilized to lift and lower substrate(s) 255 as the substrates 255 are loaded on and/or unloaded from the cassette 230.

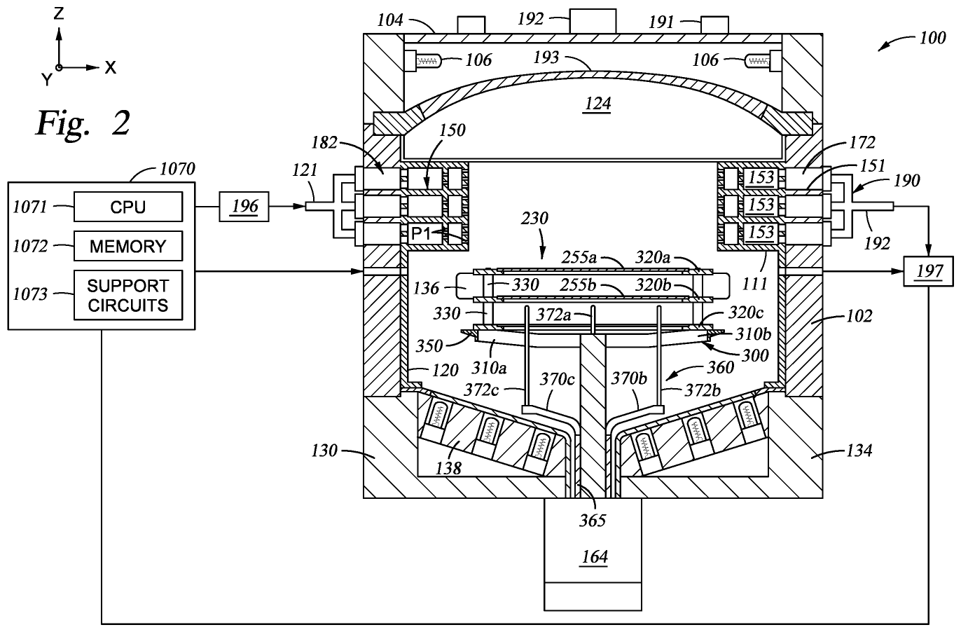

FIGS. 2-4 illustrate the manipulation and movement of substrates 255 from the cassette after processing. FIG. 2 is a schematic cross-sectional side view of the processing apparatus 100 shown in FIG. 1, with the cassette 230 in an unloading position. In various embodiments, because the lift pin assembly 360 and lift pins 370a, 370b, 370c are positioned below the cassette 230 in the processing position, substrates 255 are loaded into the cassette 230 top-down and un-loaded bottom-up.

In FIG. 2, the lower substrate 255c has been removed, and the lift pin assembly 360 is ready to lift the center substrate 255b to a position adjacent an opening 136, where the center substrate 255b can be accessed by a robot arm 375 (not shown). Opening 136 is formed through the one or more sidewalls of the chamber body 130. The opening 136 may be used to transfer the substrates 255 to or from the cassette 230, e.g., in and out of the processing volume 124. In one or more embodiments, the opening 136 includes a slit valve. In one or more embodiments, the opening 136 may be connected to any suitable valve that enables the passage of substrates 255 therethrough. In some embodiments, the cassette 230 is rotatable during processing. In such embodiments, the cassette 230 has a loading/unloading position in which the cassette 230 is oriented in the position illustrated in FIG. 9, enabling the substrates 255 to be loaded and unloaded through the opening 136, without interference by the cassette supporting arms 315.

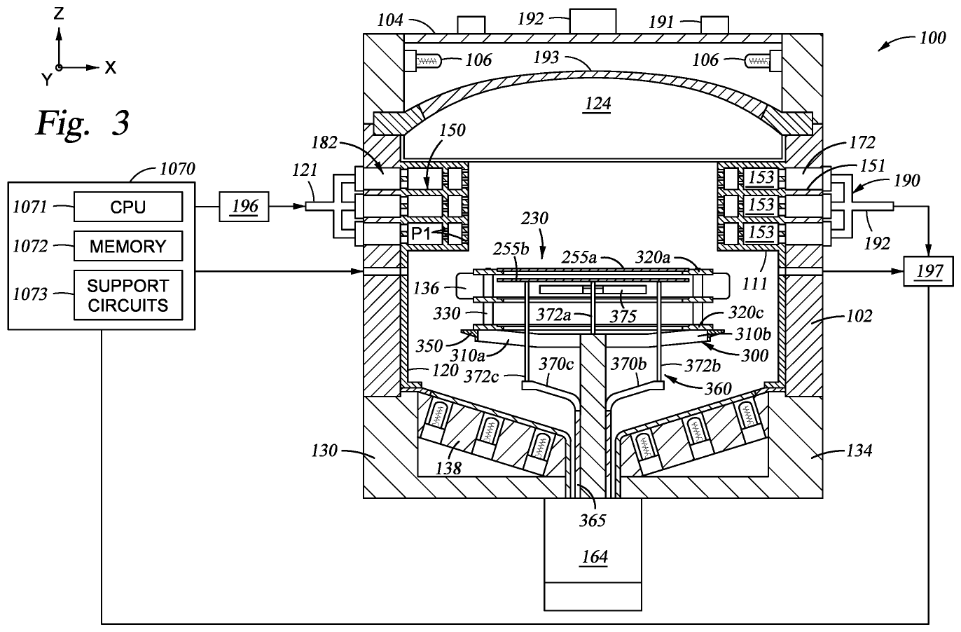

FIG. 3 is a schematic side cross-sectional view of the processing apparatus 100 of FIG. 2, with a substrate 255b lifted by the lift pins 372a, 372b, 372c to a position in front of opening 136 and just above the robot arm 375. The robot arm 375 which includes two fingers 375a, 375b (as shown in FIG. 9) constructed and arranged to straddle lift pin 372a and position itself just below the substrate 255b. In this position, the split fingers of the robot arm 375 are ready to receive the substrate 255b as the lift pins 372a, 372b, 372c are lowered.

In FIG. 3 the lift pin assembly 360 raises the lower substrate 255c for removal by the robot arm 375. Once the lower substrate 255c has been removed the lift pin assembly 360 will be raised through the inside of a lower substrate support ring 320c in order to lift the center substrate 255b from a center substrate support ring 320b for removal by the robot arm 375. This process is then repeated in order to lift the upper substrate 255a for removal.

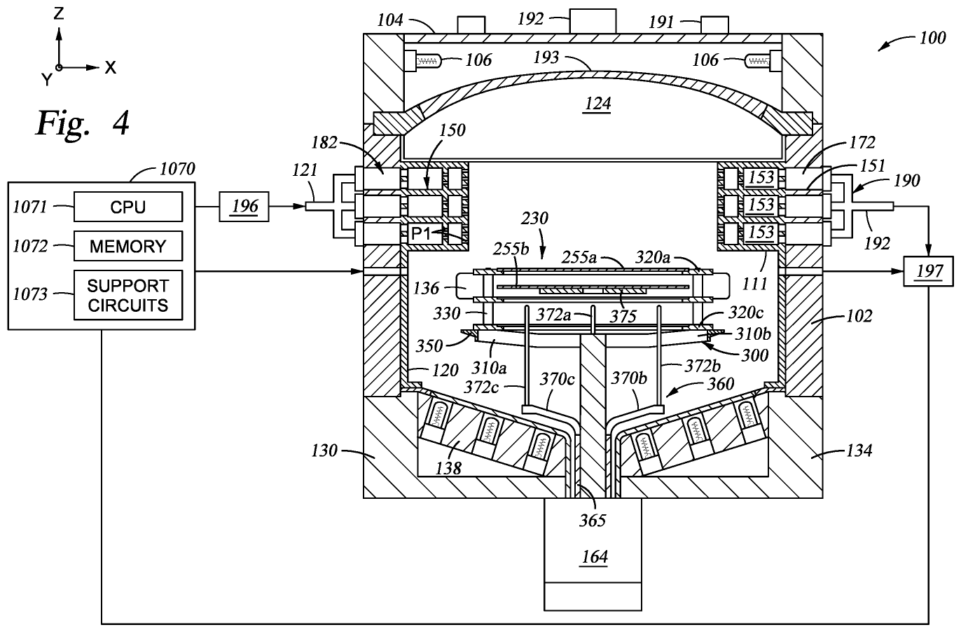

FIG. 4 is a schematic top cross-sectional view of the processing apparatus 100 shown in FIGS. 2 and 3, with the second substrate 255b deposited on robot arm 375 and the lift pins 372a, 372b, 372c retracted. The substrate 255b can now be removed from the processing volume 124 by the robot via the opening 136. This process will be repeated until remaining substrate 255a is removed and the cassette 230 is empty. It is understood that, although the above process is described as being repeated three times to remove substrates 255a, 255b, and 255c, in various embodiments, the process can be repeated any number of times, such as 2 times, 4 times, 6 times, or 12 times, depending on how many substrates the cassette 230 is able to hold.

The processing apparatus 100 may include one or more temperature sensors 191, 192, such as optical pyrometers, which measure one or more temperatures within the processing apparatus 100 (such as on the surfaces of the window 193, one or more surfaces of the substrates 255 and/or the cassette 230). In some embodiments, the one or more temperature sensors 191, 192 are disposed on the lid 104.

The processing apparatus 100 includes a controller 1070 configured to control the processing apparatus 100 or components thereof. For example, the controller 1070 may control the operation of components of the processing apparatus 100 using a direct control of the components or by controlling controllers associated with the components. In operation, the controller 1070 enables data collection and feedback from the respective chambers to coordinate and control performance of the processing apparatus 100.

The controller 1070 generally includes a central processing unit (CPU) 1071, a memory 1072, and support circuits 1073. The CPU 1071 may be one of any form of a general purpose processor that can be used in an industrial setting. The memory 1072, or non-transitory computer readable medium, is accessible by the CPU 1071 and may be one or more of memory such as random access memory (RAM), read only memory (ROM), floppy disk, hard disk, or any other form of digital storage, local or remote. The support circuits 1073 are coupled to the CPU 1071 and may include cache, clock circuits, input/output subsystems, power supplies, and the like.

The various methods and operations disclosed herein may generally be implemented under the control of the CPU 1071 by the CPU 1071 executing computer instruction code stored in the memory 1072 (or in memory of a particular processing chamber) as, e.g., a software routine. When the computer instruction code is executed by the CPU 1071, the CPU 1071 controls the components of the processing chamber 100 to conduct operations in accordance with the various methods and operations described herein. In one embodiment, which can be combined with other embodiments, the memory 1072 (a non-transitory computer readable medium) includes instructions stored therein that, when executed, cause the methods and operations described herein to be conducted. The controller 1070 can be in communication with the heat sources, the gas sources, and/or the vacuum pump(s) of the processing apparatus 100, for example, to cause a plurality of operations to be conducted.

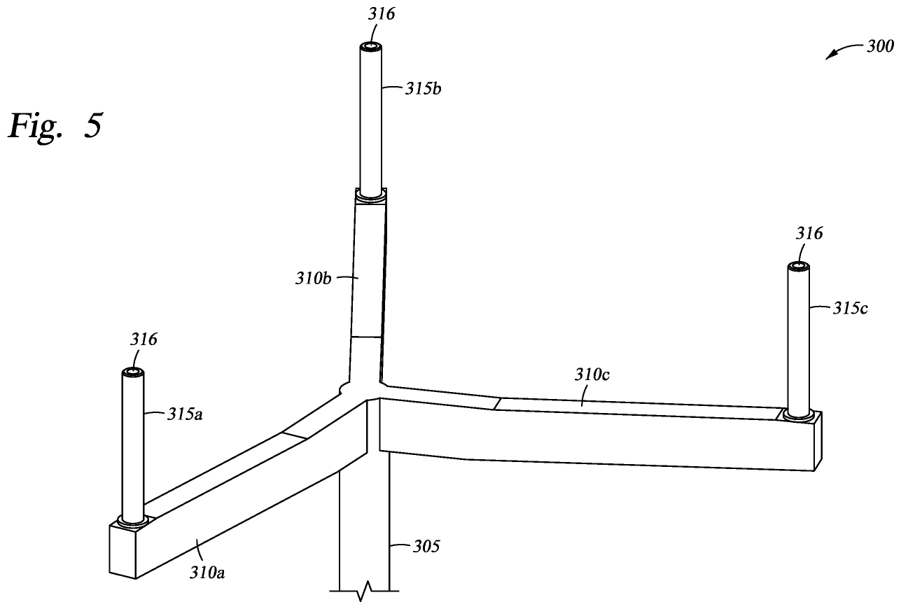

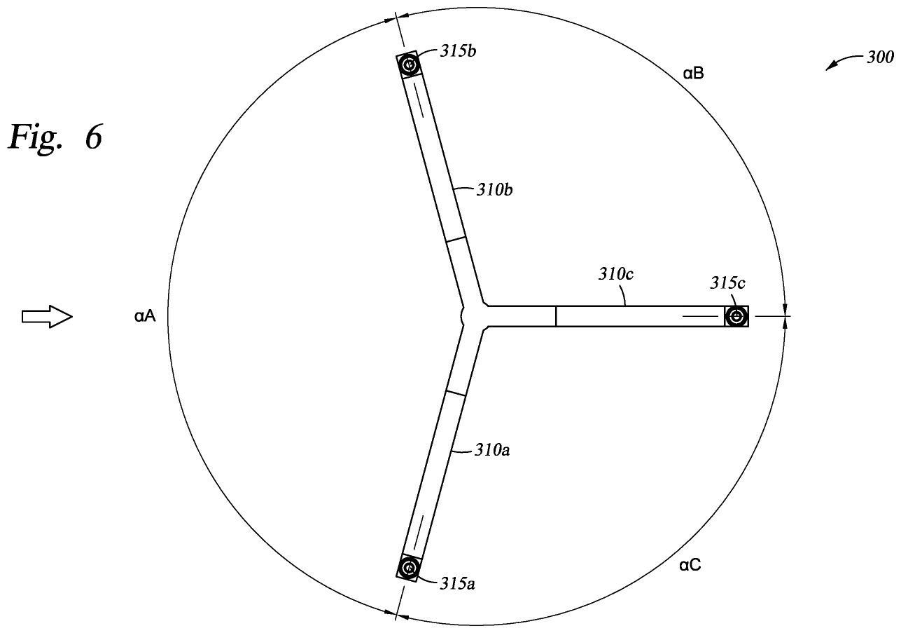

FIG. 5 is a perspective view of an upper portion of the pedestal assembly 300 used to support the cassette 230 shown in FIGS. 1-4. FIG. 6 is a top view of the pedestal assembly 300. Pedestal assembly 300 includes a vertical shaft 305 extending from a motor 164 (not shown) which is configured to independently raise, lower, and/or rotate the cassette 230. At an upper end of the shaft 305 are a plurality of outwardly extending arms 310a, 310b, and 310c, each of which is provided with an upright cassette supporting arm 315a, 315b, 315c at a distal end thereof. The pedestal assembly may be a uni-body or monolithic body design made of a material, such as quartz, in order to allow for a compact surface area to be able to fit inside the processing chamber. In the embodiment shown, the supporting arms are integrally formed on the arms.

As illustrated in FIG. 6, distinct angles A, B, C are formed between adjacent pairs of arms 310a, 310b, 310c. In various embodiments, angle A, between arms 310a, 310b, is larger than angles B and C formed between arms 310b, 310c and 310c, 310a respectively. Enlarging angle A relative to angles B and C facilitates the lateral passage of a substrate 255 through the two cassette supporting arms 315a, 315b and into the cassette 230. Therefore, both the length of the arms 310a, 310b as well as the angle A between the arms 310a, 310b results in a minimum distance between the supporting arms wide enough to exceed the outer diameter of a substrate 255 and permit its passage between the arms 310a, 310b and into the cassette 230. Angle A may have an angle greater than 120 degrees, such as an angle greater than 130 degrees, such as an angle greater than 150 degrees such as an angle greater than 170 degrees, to ensure that the pedestal assembly remains compact but is still large enough to allow for a substrate to be transferred into the cassette 230. For example, in the case of a substrate having an outer diameter of 300 mm, the inside distance between arms 310a, 310b will exceed 300 mm. While the example is of a 300 mm substrate, it will be understood that the arms could be designed to exceed the outer diameter of a substrate having a diameter greater than 100 mm such a diameter of 200 mm, or a diameter of 400 mm or any other diameter.

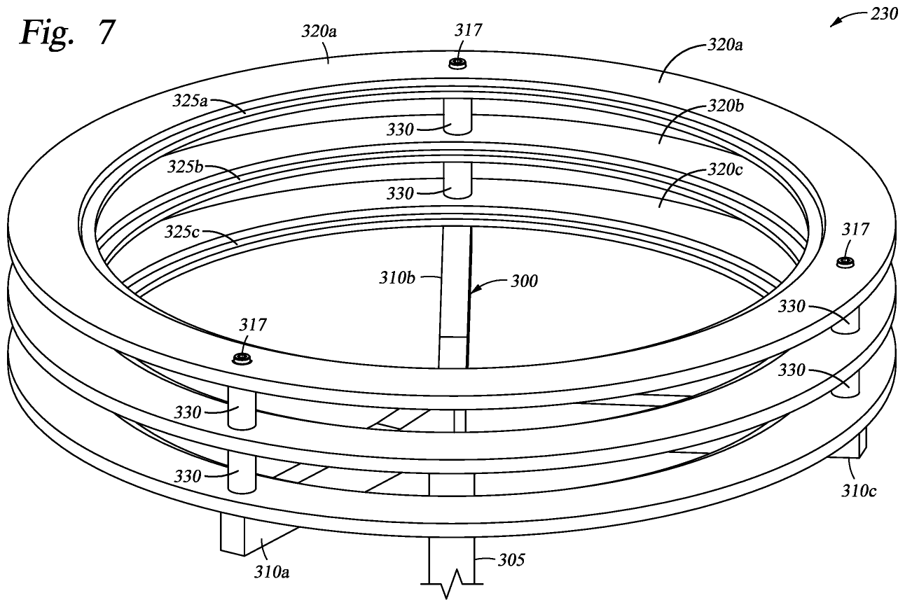

The purpose of the vertical cassette supporting arms 315a, 315b, 315c at the distal end of each horizontal arm 310a, 310b, 310c of the pedestal assembly 300 is to support the various levels of the cassette 230, each level housing a substrate 255 for processing. The cassette of FIG. 7, for example, includes three levels. Each level is made up of a substrate support ring 320a, 320b, 320c with each ring including an inwardly facing ridge 325a, 325b, 325c on the inner circumference of the substrate support rings. The ridge 325 of each ring 320 has an inner diameter slightly smaller than the outer diameter of a substrate 255. Therefore, while the inner diameter of the ring 320 is slightly larger than the outer diameter of a substrate, the smaller inner diameter of the ridge 325 supports the substrate. In this manner, each substrate can be held in a predetermined position in the cassette 230 during processing.

In some embodiments, the levels are vertically separated by utilizing hollow spacers 330 that are installed coaxially around the cassette supporting arms 315a, 315b, 315c (FIG. 5). In FIG. 7, for example, the cassette 230 has three levels for housing three substrates 255. The arrangement utilizes two sets of spacers 330 to facilitate the separation of the upper two levels, e.g., rings 320a, 320b. The lower substrate support ring 320c may include three holes (not shown) that correspond to the three vertical cassette supporting arms 315a, 315b, 315c. The three holes will be aligned coaxially around the cassette supporting arms 315a, 315b, 315c so that the lower substrate support ring 320c can be positioned against the upper surfaces of each horizontal arm 310a, 310b, 310c. A first set of spacers 330 is then positioned around each of the corresponding vertical cassette supporting arms 315a, 310b, 310c so that the lower surface of each spacer 330 is positioned against the top surface of the lower substrate support ring 320c.

The middle substrate support ring 320b may include three through holes that align with the three holes of the lower substrate support ring 320 c. The three through holes will be aligned coaxially around the cassette supporting arms 315a, 315b, 315c so that the middle substrate support ring 320b can be positioned against the upper surfaces of each of the first set of spacers 330. This process is then repeated with a second set of spacers 330 and the upper support ring 320a. By choosing the height of the spacers 330, the vertical distance between the support rings can be predetermined. While the current embodiment is shown to have three vertical cassette supporting arms 315a, 315b, 315c as well as three support rings 320a, 320b, 320c. It should be understood that the cassette 230 can have more than three vertical cassette supporting arms 315 such as four vertical cassette supporting arms 315, or five vertical cassette supporting arms 315 as well as have more or less than three support rings 320 such as two support rings 320, six support rings 320, or twelve support rings 320. In general, any number of combinations of number of vertical cassette supporting arms 315 as well as substrate support rings 320 can be implemented, such five vertical cassette supporting arms 315 and two substrate support rings 320, or three vertical cassette supporting arms 315 and twelve substrate support rings 320. It should be further understood that there could be any number of holes going through each substrate support ring, as well as any number of spacers 330 between each pair of neighboring substrate support rings.

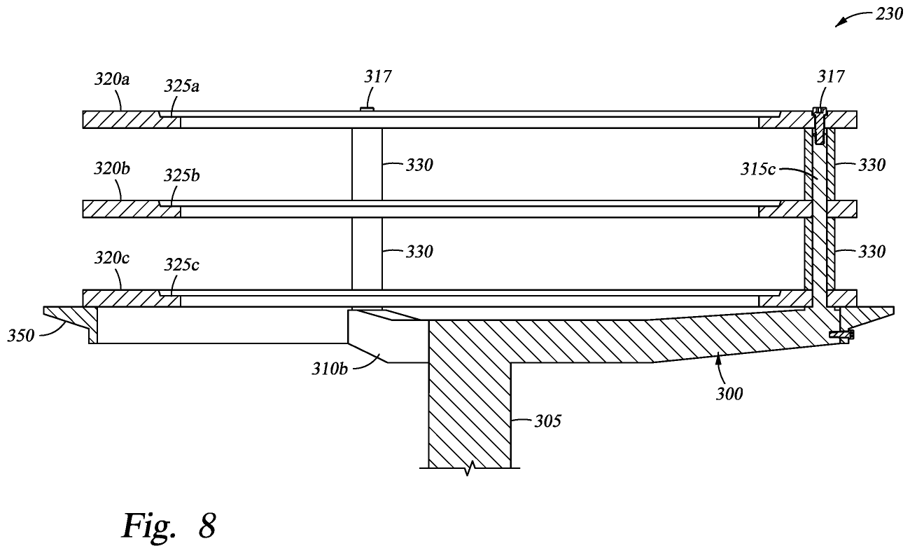

FIG. 8 is a schematic side view of the cassette 230, partially in section. The right side of FIG. 8 illustrates a cassette supporting arm 315c of the cassette having two spacers 330 stacked thereupon with a substrate support ring 320b held between the pair of spacers 330. Two additional support rings 320a, 320c are shown, one below the lower spacer adjacent seal ring 350, and one at an upper end of the upper spacer 330 where the support ring 320a is retained by a fastener 317. In all, three support rings 320 are shown, each with an inner facing ledge 325a, 325b, 325c for supporting a substrate 255. A second cassette supporting arm 310b with its own spacers 300 is visible towards the rear of the cassette 230 (the third vertical member is not visible in FIG. 8).

FIG. 9 is a top view, partially in section, depicting the pedestal arms 310a, 310b, 310c with their cassette supporting arms (spacers 330 and fasteners 317 obscure the view) and their connection to substrate support ring 320a. Also shown are lift pins 372a, 372b, 372c. A robot arm 375 having two bifurcated fingers 375a, 375b and a substrate 255 are depicted in dotted lines.

FIG. 9 generally illustrates how, in various embodiments, substrates 255 are loaded into a cassette 230 (note arrow 905) having the pedestal design disclosed herein. As shown, the substrate 255 is insertable (or removable) by utilizing the enlarged angle A formed between cassette supporting arms 315 at the end of horizontal arms 310a, 310b. Considering FIG. 9 in conjunction with FIG. 6, it can be appreciated that the length of horizontal arms 310a, 310b and angle A between horizontal arms 310a and 310b results in dimension 901, the inside distance between cassette supporting arms 315a, 315b. Comparing dimension 901 to dimension 902, the outer diameter of substrate 255, it can be appreciated that the difference, dimension 903, provides ample room for the lateral insertion of a substrate into the cassette 230 so long as the pedestal assembly 300 is in the rotational position shown in FIG. 9.

Additionally, the lift pins 372a, 372b, 372c are also radially arranged into a loading/unloading position so as not interfere with the bifurcated robot fingers 375a, 375b that extend into the cassette 230 to deposit the substrate 255 onto the lift pins 372 as they are raised in a manner that lifts the substrate from the fingers. Thereafter, the lift pins 372 lower the substrate 255 to its predetermined position in the substrate support ring 320a of the cassette 230. The same process is repeated for each substrate to be batch-processed in the chamber. Each time a new substrate is to be loaded, the cassette axially align the next empty support ring with opening 136.

Benefits of the present disclosure include a reduced number of individual parts (due to the incorporation of the cassette supporting arms into the pedestal assembly), as well as a smaller overall footprint of the cassette assembly (e.g., in terms of width), enabling the loading, unloading, and processing of multiple substrates at the same time.

While the foregoing is directed to embodiments of the present disclosure, other and further embodiments of the disclosure may be devised without departing from the basic scope thereof, and the scope thereof is determined by the claims that follow.

What is claimed is:

1. A cassette support system, comprising:
a pedestal assembly, comprising:
a shaft;
a plurality of arms coupled to the shaft and extending radially from the shaft, wherein at least two radially adjacent arms included in the plurality of arms are separated by an angle of about 130 degrees or greater;
a plurality of cassette supporting arms, each cassette supporting arm extending from an end of an arm included in the plurality of arms; and
one or more substrate support rings, each substrate support ring comprising:
a ridge defined along an inner circumference of the substrate support ring, the ridge configured to receive a substrate.

2. The cassette support system of claim 1, wherein the pedestal assembly comprises quartz.

3. The cassette support system of claim 1, wherein the shaft and the plurality of arms form a monolithic body.

4. The cassette support system of claim 1, wherein the pedestal assembly comprises one or more spacers, wherein each spacer is disposed around a corresponding cassette supporting arm between a pair of neighboring substrate support rings included in the one or more substrate support rings.

5. The cassette support system of claim 1, wherein the angle is about 150 degrees or greater.

6. The cassette support system of claim 1, wherein the angle is about 170 degrees or greater.

7. The cassette support system of claim 4, wherein the one or more substrate support rings comprise at least three substrate support rings separated by at least two sets of spacers included in the one or more spacers.

8. The cassette support system of claim 4, wherein the one or more substrate support rings comprise at least four substrate support rings separated by at least three sets of spacers included in the one or more spacers.

9. The cassette support system of claim 1, wherein the plurality of arms comprises at least two horizontal arms.

10. The cassette support system of claim 1, wherein the pedestal assembly comprises at least three arms and at least three cassette supporting arms.

11. The cassette support system of claim 4, wherein a distance between the substrate support rings corresponds to a height of the one or more spacers disposed on the arms.

12. A processing system, comprising:
a processing chamber; and
the cassette support system of claim 1.

13. The processing system of claim 12, further comprising a lift pin assembly having a plurality of lift pins, wherein the lift pin assembly is vertically adjustable.

14. The processing system of claim 13, wherein a shaft of the lift pin assembly is coaxially arranged outside of the shaft.

15. The cassette support system of claim 1, wherein at least one of the one or more substrate support rings comprises a plurality of through holes.

16. The cassette support system of claim 15, wherein the plurality of cassette supporting arms are disposed within the plurality of through holes.

17. The cassette support system of claim 1, wherein the angle forms a minimum distance between the ends of the radially adjacent arms, wherein the minimum distance is greater than a diameter of the inner circumference of the substrate support ring.

18. The cassette support system of claim 17, wherein the minimum distance is greater than 200 mm.

19. A cassette support system, comprising:
a pedestal assembly, comprising:
a shaft;
a plurality of arms coupled to the shaft and extending radially from the shaft, wherein at least two radially adjacent arms included in the plurality of arms are separated by an angle of about 130 degrees or greater;
a plurality of cassette supporting arms, each cassette supporting arm extending from a different arm included in the plurality of arms; and
at least one substrate support ring, comprising:
a ridge defined along an inner circumference of each of the at least one substrate support ring.

20. A cassette support system, comprising:
a pedestal assembly, comprising:
a shaft;
three or more arms coupled to the shaft and extending radially from the shaft, wherein two radially adjacent arms included in the three or more arms are separated by an angle of about 130 degrees or greater;
three or more cassette supporting arms, each cassette supporting arm extending from a different arm of the three or more arms; and
three or more substrate support rings, comprising:
a ridge defined along an inner circumference of each of the substrate support rings;
a first set of spacers disposed between a first substrate support ring and a second substrate support ring, wherein each spacer is disposed around a corresponding vertical cassette supporting arm; and
a second set of spacers disposed between the second substrate support ring and a third substrate support ring, wherein each spacer is disposed around a corresponding vertical cassette supporting arm.
